(19) United States
(12) Patent Application Publication
(10) Pub. No.: US 2025/0107339 A1
(43) Pub. Date: Mar. 27, 2025

(54) DISPLAY DEVICE

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/672,685

(22) Filed: May 23, 2024

(30) Foreign Application Priority Data
Sep. 21, 2023 (KR) 10-2023-0126385

(51) Int. Cl. H10K 59/122; H10K 59/00

(52) U.S. Cl. CPC H10K 59/122; H10K 59/771

(57) ABSTRACT

A display device according to an embodiment includes a transistor located on a substrate, a first electrode electrically connected to the transistor; a first functional layer located on the first electrode, a light emitting layer located on the first functional layer, a second functional layer located on the light emitting layer, a second electrode located on the second functional layer; a pixel defining layer located on the first electrode, and a separator located on the pixel defining layer, wherein the separator includes a first sub-layer including an insulating material, and a second sub-layer located on the first sub-layer and including a metal material, and an end of the second electrode contacts a side surface of the second sub-layer.

### CROSS-REFERENCE TO RELATED APPLICATION

This application claims priority to and the benefit of Korean Patent Application No. 10-2023-0126385 under 35 U.S.C. § 119, filed at the Korean Intellectual Property Office (KIPO) on Sep. 21, 2023, the entire contents of which are incorporated herein by reference.

### BACKGROUND

### 1. Technical Field

The disclosure relates to a display device, and more specifically, to a display device that prevents current leakage and improves contact between neighboring pixels.

### 2. Description of the Related Art

A light emitting display device includes a light emitting element (LED).

A light emitting element is a structure in which a functional thin film in the form of a light emitting layer is inserted between an anode electrode and a cathode electrode. It is a device that emits light in case that a hole is injected from the anode, an electron is injected from the cathode, and an exciton is formed by the combination of the electron and the hole within the light emitting layer, and this exciton recombines to emit light.

Light emitting display devices are attracting attention as next-generation display devices not only because they are lightweight and thin, but also because of their advantages such as wide viewing angles, fast response speeds, and low power consumption.

Recently, with the use of high-resolution display devices, the size of one pixel is becoming smaller and the distance between neighboring pixels is becoming narrower.

### SUMMARY

Embodiments are intended to provide a display device that prevents lateral current leakage and improves electrode contact in a high-resolution display device.

The technical objectives to be achieved by the disclosure are not limited to those described herein, and other technical objectives that are not mentioned herein would be clearly understood by a person skilled in the art from the description of the disclosure.

A display device according to an embodiment includes a transistor located on a substrate, a first electrode electrically connected to the transistor, a first functional layer located on the first electrode, a light emitting layer located on the first functional layer, a second functional layer located on the light emitting layer, a second electrode located on the second functional layer, a pixel defining layer located on the first electrode, and a separator located on the pixel defining layer, wherein the separator includes a first sub-layer including an insulating material, and a second sub-layer located on the first sub-layer and including a metal material, and an end of the second electrode contacts a side surface of the second sub-layer.

The separator may further include a third sub-layer located on the second sub-layer, and a width of the third sub-layer may be greater than a width of the second sub-layer.

The third sub-layer may include a metal material.

The first sub-layer may have a first thickness, and the second sub-layer may have a second thickness, and the first thickness may be greater than the second thickness.

The first thickness may be greater than one-half of a sum of the first thickness and the second thickness, and the second thickness may be less than one-half of a sum of the first thickness and the second thickness.

An end of the first functional layer may contact a side surface of the first sub-layer.

The first functional layer may include a conductive hole injection layer.

The first sub-layer may include silicon nitride, silicon oxide, silicon nitrate, or an organic insulating material.

The second sub-layer and the third sub-layer may include at least one of Mo, W, Ti, Al, and TiN.

Ends of the light emitting layer and the second functional layer may contact a side surface of the first sub-layer.

The first functional layer, the second functional layer, and the second electrode may be electrically disconnected between adjacent light emitting areas.

A display device according to an embodiment includes a transistor located on a substrate, a first electrode electrically connected to the transistor, a first functional layer located on the first electrode, a light emitting layer located on the first functional layer, a second functional layer located on the light emitting layer, a second electrode located on the second functional layer, a pixel defining layer located on the first electrode, and a separator located on the pixel defining layer, wherein the separator includes a first sub-layer including an insulating material, a second sub-layer located on the first sub-layer and including a metal material, and a third sub-layer located on the second sub-layer, wherein an end of the second electrode contacts a side surface of the second sub-layer, and an end of the first functional layer is adjacent to a side surface of the first sub-layer.

A width of the third sub-layer may be greater than a width of the second sub-layer.

The first sub-layer may have a first thickness, and the second sub-layer may have a second thickness, and the first thickness may be greater than the second thickness.

The first thickness may be more than one-half of a sum of the first thickness and the second thickness, and the second thickness may be less than one-half of a sum of the first thickness and the second thickness.

The first functional layer may include a conductive hole injection layer.

Ends of the light emitting layer and the second functional layer may contact a side surface of the first sub-layer.

The first functional layer, the second functional layer, and the second electrode may be electrically disconnected between adjacent light emitting areas.

The display device may further include at least two light emitting layers that overlap in a direction perpendicular to the substrate.

The at least two light emitting layers may contact a side surface of the first sub-layer.

According to embodiments, a display device that prevents lateral current leakage and improves electrode contact in a high-resolution display device is provided.

### BRIEF DESCRIPTION OF THE DRAWINGS

FIG. 1 schematically shows a plan view of multiple pixels according to an embodiment.

FIG. 2 schematically shows a cross-section of an adjacent pixel according to an embodiment.

FIG. 3 schematically shows a cross-section of an area adjacent to a separator according to an embodiment.

FIG. 4 schematically shows the stacked structure of multiple pixels.

FIG. 5 schematically shows current density with respect to voltage in case that the resolution is 2×2, HD, FHD, and QHD.

FIG. 6 schematically shows efficiency with respect to voltage in case that the resolution is 2×2, HD, FHD, and QHD.

FIG. 7 schematically shows a plan view of multiple pixels according to an embodiment.

FIG. 8 schematically shows a cross-sectional view of a pixel according to an embodiment.

FIG. 9 schematically shows a stacked structure of a light emitting element according to an embodiment.

FIG. 10, FIG. 11, FIG. 12 and FIG. 13 schematically illustrate a method of manufacturing a display device according to an embodiment.

### DETAILED DESCRIPTION OF THE EMBODIMENTS

Hereinafter, with reference to the attached drawings, various embodiments of the disclosure will be described in detail so that those skilled in the art can easily implement the disclosure.

The disclosure may be implemented in many different forms and is not limited to the embodiments described herein.

In order to clearly explain the disclosure, parts that are not relevant to the description are omitted, and identical or similar components are assigned the same reference numerals throughout the specification.

The size and thickness of each component shown in the drawings may be arbitrarily shown for convenience of explanation, so the disclosure is not necessarily limited to that which is shown.

In the drawings, the thickness may be enlarged or exaggerated to clearly express various layers and areas.

In case that a part of a layer, membrane, region, or plate is said to be “above” or “on” another part, this includes not only cases where it is “directly above” another part, but also cases where there is another part in between.

In case that a part is said to be “directly on top” of another part, it means that there is no other part in between.

Being “above” or “on” a reference part means being located above or below the reference part, and does not necessarily mean being located “above” or “on” it in the direction opposite to gravity.

Throughout the specification, in case that a part is said to “include,” “comprise,” or “have” a certain element, this means that it may include the certain element and/or may further include other elements, rather than excluding other elements, unless specifically stated to the contrary.

Throughout the specification, in case that reference is made to “on a plane” or “in a plan view,” this may indicate a case where the target part is viewed from above, and in case that reference is made to “in cross-section” or “in a cross-sectional view,” this may indicate a case where a cross-section of the target part is cut vertically and viewed from a side.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

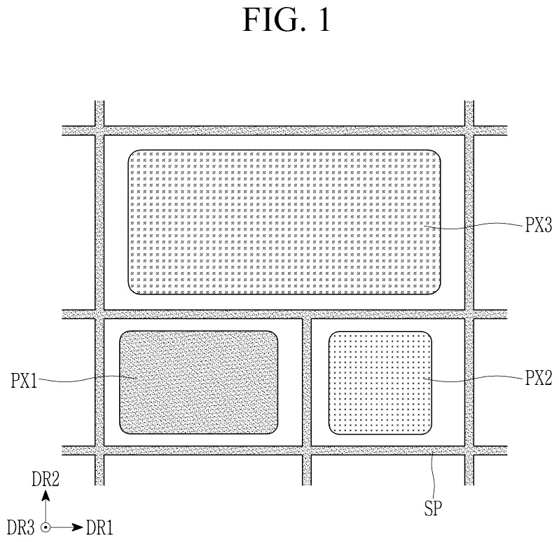

Hereinafter, a display device according to an embodiment will be described with reference to FIG. 1 to FIG. 3.

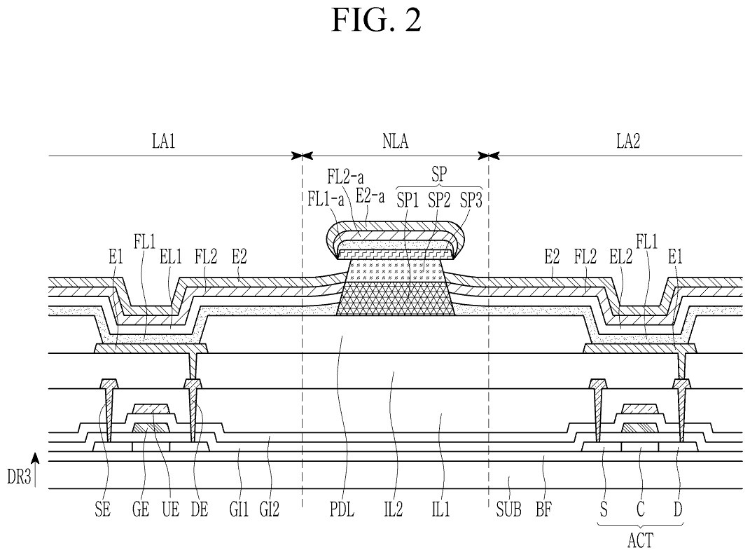

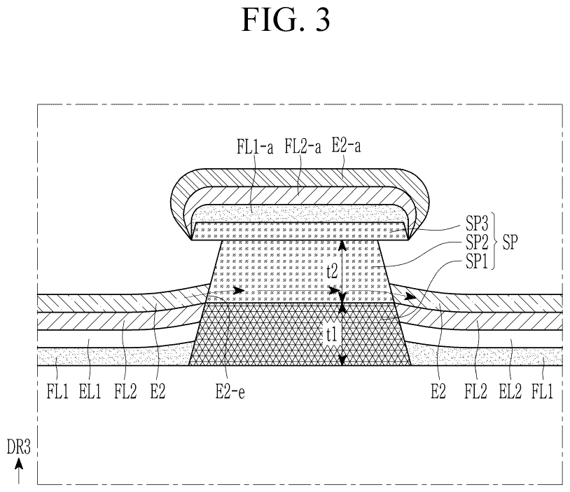

FIG. 1 is a simplified plan view of multiple pixels according to an embodiment, FIG. 2 is a simplified cross-section of an adjacent pixel according to an embodiment, and FIG. 3 is a simplified cross-section of an area adjacent to a separator according to an embodiment.

Referring to FIG. 1, a display device according to an embodiment may include one or more first pixels PX1, second pixels PX2, and third pixels PX3 disposed on a substrate.

Each pixel PX1, PX2, PX3 may include one or more transistors and a light emitting element connected thereto.

According to an embodiment, for example, the first pixel PX1 may emit red light, the second pixel PX2 may emit green light, and the third pixel PX3 may emit blue light.

The display device may include a light emitting area that emits red light, green light, and blue light, and a non-light emitting area other than the light-emitting area.

Each of the first pixel PX1, the second pixel PX2, and the third pixel PX3 according to an embodiment is shown as a square shape with rounded corners, but is not limited to this shape and may be transformed into various shapes.

Each of the first pixel PX1, the second pixel PX2, and the third pixel PX3 is shown in a square shape with different areas, but is not limited to this and may be modified to have various areas.

An arrangement of the pixels in which the first pixel PX1 and the second pixel PX2 are adjacent to each other in the first direction DR1, the first pixel PX1 and the third pixel PX3 are adjacent to each other in the second direction DR2, and the second pixel PX2 and the third pixel PX3 are adjacent to each other in the second direction DR2 is shown, but the embodiments are not limited to this, and arrangement of the first pixel PX1, the second pixel PX2 and the third pixel PX3 may be arranged in various configurations/shapes.

A display device according to an embodiment may include a separator SP located between adjacent first pixels PX1, second pixels PX2, and third pixels PX3.

In a plan view, the separator SP may overlap a non-light emitting area and may have a grid shape.

The separator SP may allow a layer located on top of the separator SP to be disconnected near the separator SP.

The separator SP may serve to separate the second electrode, which will be described below, and may reduce leakage current between adjacent pixels.

Depending on embodiments, the separator SP may be made of (or include) a transparent organic material or may be made of a black material to prevent external light from being reflected.

Hereinafter, the separator SP will be described in more detail with reference to FIG. 2 and FIG. 3.

The stacked structure of the light emitting areas (LA1, LA2) included in each pixel will be described first.

The light emitting areas LA1 and LA2 according to an embodiment may include a substrate SUB.

The substrate SUB may include a flexible material such as plastic that may be bent, folded, or rolled.

A buffer layer BF may be located on the substrate SUB.

The buffer layer BF may include, e.g., silicon nitride (SiNₓ), silicon oxide (SiO₂), or silicon nitride.

The buffer layer BF may be located between the substrate SUB and a semiconductor layer ACT, and may improve the properties of the polycrystalline silicon by blocking impurities from the substrate SUB during the crystallization process to form polycrystalline silicon, by planarizing, the stress of the semiconductor layer ACT formed on the buffer layer BF may be alleviated.

The semiconductor layer ACT may be located on the buffer layer BF.

The semiconductor layer ACT may be made of (or include) polycrystalline silicon or oxide semiconductor.

The semiconductor layer ACT may include a channel region C, a source region S, and a drain region D.

The source region S and drain region D may be respectively arranged on both sides of the channel region C.

The channel region C may include an intrinsic semiconductor that is not doped with an impurity, and the source region S and the drain region D may include an impurity semiconductor that is doped with a conductive impurity.

The semiconductor layer ACT may be made of (or include), e.g., an oxide semiconductor, in which case a separate protective layer (not shown) may be added to protect the oxide semiconductor material, which may be vulnerable to external factor such as high temperature.

A first gate insulating layer GI1 may be located on the semiconductor layer ACT.

The first gate insulating layer GI1 may be a single layer or a multilayer including, e.g., at least one of silicon nitride (SiNₓ), silicon oxide (SiO₂), and silicon nitride oxide. A gate electrode GE may be located on the first gate insulating layer GI1.

The gate electrode GE may be a multilayer of metal layers including, e.g., at least one of copper (Cu), copper alloy, aluminum (Al), aluminum alloy, molybdenum (Mo), and molybdenum alloy.

A second gate insulating layer GI2 may be located on the gate electrode GE and the first gate insulating layer GI1.

The second gate insulating layer GI2 may be a single layer or a multilayer including at least one of silicon nitride (SiNₓ), silicon oxide (SiO₂), and silicon nitride oxide.

A capacitor electrode UE may be located on the second gate insulating layer GI2.

The capacitor electrode UE may overlap the gate electrode GE and form a capacitor.

An interlayer insulating layer IL1 may be located on the capacitor electrode UE and the first gate insulating layer GI1.

The interlayer insulating layer IL1 may include silicon nitride (SiNₓ), silicon oxide (SiO₂), or silicon nitride oxide.

Openings exposing the source region S and drain region D may be located in the interlayer insulating layer IL1.

A source electrode SE and a drain electrode DE may be located on the interlayer insulating layer IL1.

The source electrode SE and drain electrode DE may be electrically connected to the source region S and drain region D of the semiconductor layer ACT through openings formed in the interlayer insulating layer IL1 and the first gate insulating layer GI1, respectively.

A protective layer IL2 may be located on the interlayer insulating layer IL1, the source electrode SE, and the drain electrode DE.

The protective layer IL2 may cover (or overlap) and flatten the interlayer insulating layer IL1, the source electrode SE, and the drain electrode DE, so that the first electrode E1 may be formed on the protective layer IL2 without taking any other steps.

This protective layer IL2 may be made of (or include) an organic material such as polyacrylate resin or polyimide resin, or a laminated layer of an organic material and an inorganic material.

The first electrode E1 may be located on the protective layer IL2.

The first electrode E1 may be connected to the drain electrode DE through an opening in the protective layer IL2.

A driving transistor including the gate electrode GE, the semiconductor layer ACT, the source electrode SE, and the drain electrode DE may be connected to the first electrode E1 to supply a driving current to the light emitting element.

In addition to the driving transistor shown in FIG. 2, the display device according to the embodiment may include a switching transistor (not shown) connected to the data line and transmitting a data voltage in response to the scan signal, and a switching transistor (not shown) connected to the driving transistor and driven in response to the scan signal. It may further include a compensation transistor (not shown) that compensates for the threshold voltage of the transistor.

A pixel defining layer PDL may be located on the protective layer IL2 and the first electrode E1, and the pixel defining layer PDL may have a pixel opening that overlaps the first electrode E1 and defines a light emitting area.

The pixel opening may have a planar shape substantially similar to that of the first electrode E1, and may have a diamond or octagonal shape similar to a diamond in plan, but is not limited thereto and may have any shape such as a square or polygon.

The pixel defining layer PDL may include an organic material such as polyacrylate resin or polyimide resin, or a silica-based inorganic material.

Light emitting layers EL1 and EL2 may be located on the first electrode E1 overlapping the pixel opening.

The light emitting layers EL1, EL2 may be made of (or include) a low-molecular weight organic material or a high-molecular weight organic material such as poly 3,4-ethylenedioxythiophene (PEDOT).

The light emitting layers EL1 and EL2 may be located in or mostly within the pixel opening, and may also be located on the side or top of the pixel defining layer PDL.

The second electrode E2 may be located on the light emitting layers EL1 and EL2.

The second electrode E2 may receive a common voltage through a common voltage transmitter (not shown) in the non-display area.

A first functional layer FL1 may be located between the first electrode E1 and the light emitting layer EL1, and a second functional layer FL2 may be located between the light emitting layers EL1, EL2 and the second electrode E2.

The first functional layer FL1 may include at least one of a hole injection layer HIL and a hole transport layer HTL, and the second functional layer FL2 may include at least one of an electron injection layer EIL and an electron transport layer ETL.

For example, the first functional layer FL1 according to an embodiment may be a conductive p-doped hole injection layer.

The first electrode E1, the first functional layer FL1, the light emitting layers EL1 and EL2, the second functional layer FL2, and the second electrode E2 may constitute a light emitting element.

Here, the first electrode E1 may be an anode, which is a hole injection electrode, and the second electrode E2 may be a cathode, which is an electron injection electrode.

However, the embodiment is not necessarily limited to this, and the first electrode E1 may be a cathode and the second electrode E2 may be an anode depending on the driving method of the light emitting display device.

Positive holes and electrons may be injected into the light emitting layers EL1 and EL2 from the first electrode E1 and the second electrode E2, respectively. The light may be emitted in case that the exciton, which is a combination of the injected positive hole and electron, falls from the excited state to the ground state.

An encapsulation layer (not shown) may be located on the second electrode E2.

The encapsulation layer may seal the display layer by covering the top surface and the side surfaces of the display layer including the light emitting element.

Since the light emitting element may be vulnerable to moisture and oxygen, the encapsulation layer may seal the display layer and block the inflow of external moisture and oxygen.

The encapsulation layer may include one or more layers, and may be formed as a composite layer including both an inorganic layer and an organic layer, and may be formed as a triple layer in which a first inorganic layer, an organic layer, and a second inorganic layer are sequentially formed.

Hereinafter, the non-light emitting area NLA located between the emission areas (LA1 and LA2) will be discussed.

The separator SP located on the pixel defining layer PDL may be located in the non-light emitting area NLA.

The separator SP may prevent lateral leakage current of a high-resolution structure by electrically disconnecting the functional layers FL1 and FL2 and the second electrode E2 between adjacent pixels.

The functional layers FL1 and FL2, and the second electrode E2 between adjacent pixels based on the separator SP may have a disconnected shape.

The separator SP according to an embodiment may include a first sub-layer SP1, a second sub-layer SP2, and a third sub-layer SP3.

The first sub-layer SP1 may be located on the pixel defining layer PDL and may include an insulating material.

The first sub-layer SP1 may include any material for insulating the functional layers FL1 and FL2 between adjacent pixels—for example, an inorganic insulating material including silicon nitride, silicon oxide, or silicon oxynitride, or an organic insulating material.

The second sub-layer SP2 may be located on the first sub-layer SP1.

An edge of the second sub-layer SP2 may overlap the first sub-layer SP1.

A cross-section of the second sub-layer SP2 may gradually become wider toward the first sub-layer SP1.

The cross-section of the first sub-layer SP1 may also have a shape that gradually becomes wider toward the pixel defining layer PDL.

The second sub-layer SP2 may include a metal material.

For example, the second sub-layer SP2 may include at least one of Mo, W, Ti, Al, and TiN.

The second sub-layer SP2 may electrically connect the second electrode E2 that is separated by the separator SP between adjacent pixels.

According to an embodiment, ends of the first functional layer FL1, the light emitting layers EL1 and EL2, and the second functional layer FL2 may contact the side surface of the first sub-layer SP1.

The first-sub-layer SP1 including an insulating material and disposed between a first functional layer FL1, a light emitting layer EL1, and a second functional layer FL2, located in the first light-emitting area LA1 and a first functional layer FL1, a light emitting layer EL1, and a second functional layer FL2 located in the second light-emitting area LA2 may be electrically disconnected, thereby preventing current leakage between adjacent pixels.

In particular, the conductive first functional layer FL1 may be electrically disconnected by the first sub-layer SP1 to prevent leakage current.

An end of the second electrode E2 may contact a side surface of the second sub-layer SP2.

The second electrode E2 located in the first light-emitting area LA1 and the second electrode E2 located in the second light-emitting area LA2 may be disconnected by the separator SP.

However, an end of the second electrode E2 located in the first light emitting region LA1 and an end of the second electrode E2 located in the second light emitting region LA2 may be electrically connected by contacting the second sublayer SP2.

As shown in FIG. 3, the first sub-layer SP1 may have a first thickness t1, and the second sub-layer SP2 may have a second thickness t2.

In an embodiment, the first thickness t1 may be greater than the second thickness t2.

The first thickness t1 may exceed at least one-half of the thickness of the separator SP including the first sub-layer SP1 and the second sub-layer SP2.

The second thickness t2 may be less than at least one-half of the thickness of the separator SP including the first sub-layer SP1 and the second sub-layer SP2.

The first thickness t1 and the second thickness t2 may be modified to various thicknesses in order to electrically disconnect the first functional layer FL1 and electrically connect the second electrode E2.

The third sub-layer SP3 may be located on the second sub-layer SP2.

A width of the third sub-layer SP3 may be greater than a width of the second sub-layer SP2.

According to an order of the manufacturing process, the first functional layer FL1, the light emitting layers EL1, EL2, the second functional layer FL2, and the second electrode E2 formed by the front deposition after the third sublayer SP3 may be separated by an undercut formed by the third sublayer SP3 and the second sublayer SP2.

At least a part of a first functional layer FL1-a, at least a part of a second functional layer FL2-a, and at least a part of a second electrode E2-a formed by front-side deposition may be located on the third sub-layer SP3.

Although not shown in this specification, at least a part of the light emitting layers EL1 and EL2 may be located between a part of the first functional layer FL1-a and a part of the second functional layer FL2-a.

The third sub-layer SP3 may include a metal material, and for example, may include a different metal material from the second sub-layer SP2.

The thickness of the third sub-layer SP3 may be less than the thickness of the first sub-layer SP1.

The thickness of the third sub-layer SP3 may be less than or equal to the thickness of the second sub-layer SP2.

For example, the first sub-layer SP1 may include silicon nitride with a thickness of about 3000 angstroms, the second sub-layer SP2 may include molybdenum with a thickness of about 2000 angstroms, and the third sub-layer SP3 may include titanium with a thickness of about 1000 angstroms.

For example, the first sub-layer SP1 may include silicon dioxide with a thickness of about 4000 angstroms, the second sub-layer SP2 may include molybdenum with a thickness of about 1000 angstroms, and the third sub-layer SP3 may include titanium with a thickness of about 1000 angstroms.

The separator SP according to an embodiment may reduce the leakage current by electrically disconnecting the first functional layer FL1, the light emitting layers EL1, EL2, and the second functional layer FL2 between adjacent pixels through the first sub-layer SP1.

Additionally, the second electrode E2 between adjacent pixels may be electrically connected through the second sub-layer SP2.

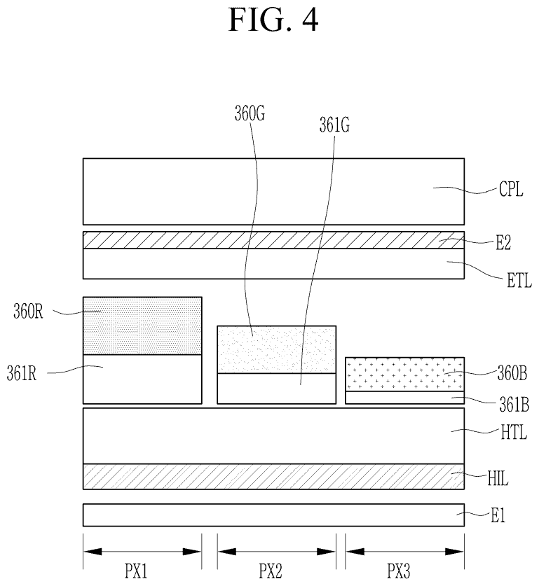

FIG. 4 to FIG. 6 will be discussed below.

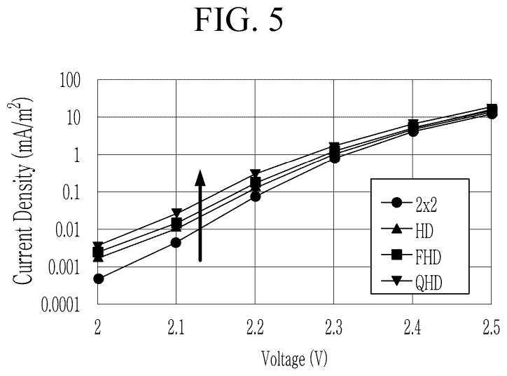

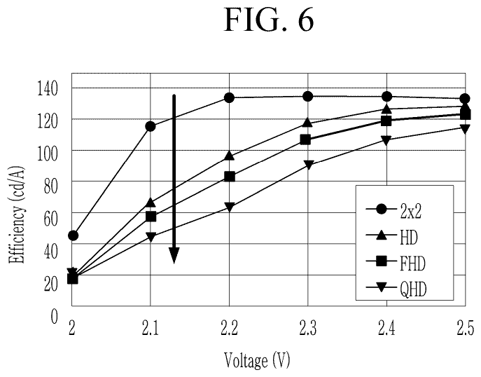

FIG. 4 schematically shows the stacked structure of multiple pixels, FIG. 5 shows current density according to voltage in case that the resolution is 2×2, HD, FHD, and QHD, and FIG. 6 shows the current density in case that the resolution is 2×2, HD, FHD, and QHD.

FIG. 4 schematically shows the stacked structure of a plurality of pixels.

Referring to FIG. 4, the hole injection layer HIL may be located on the first electrode E1.

In FIG. 4, the common configuration of each pixel PX1, PX2, and PX3 is shown as one body.

The first electrode E1 and the hole injection layer HIL may be commonly located in each pixel PX1, PX2, and PX3.

Likewise, the hole transport layer HTL may be commonly located in each pixel PX1, PX2, PX3.

Next, the first pixel PX1 may include a first auxiliary layer 361R and a first emission layer 360R.

The second pixel PX2 may also include a second auxiliary layer 361G and a second light emitting layer 360G.

The third pixel PX3 may also include a third auxiliary layer 361B and a third light emitting layer 360B.

The electron transport layer ETL may be commonly located on each of the first emission layer 360R, the second emission layer 360G, and the third emission layer 360B.

Additionally, the second electrode E2 may be located on the electron transport layer ETL, and a capping layer CPL may be located on the second electrode E2.

As shown in FIG. 4, each pixel may apply a common hole injection layer to improve hole injection characteristics.

At this time, the hole injection layer HIL may be a doped hole transport layer.

For example, the hole injection layer HIL may be a doped layer and may have higher electrical conductivity than the hole transport layer.

Therefore, side leakage current problems may occur due to conductive characteristics.

In case that leakage current occurs in this way, the efficiency of the pixel decreases and color purity deteriorates, and the leakage current may cause neighboring pixels to be weakly lit, resulting in color mixing.

In particular, in the case of high resolution, since the spacing between adjacent pixels may be narrow, the side leakage current problem may appear larger.

FIG. 5 shows current density according to voltage in case that the resolution is 2×2, HD, FHD, and QHD.

Referring to FIG. 5, it may be seen that as the resolution increases (2×2 QHD), the current density increases.

FIG. 6 shows efficiency according to voltage when the resolution is 2×2, HD, FHD, and QHD.

Referring to FIG. 6, it may be seen that as the resolution increases (2×2 QHD), efficiency decreases.

This is because, as previously explained, as resolution increases, the distance between adjacent pixels narrows and leakage current increases.

However, the display device according to this embodiment may include the separator SP located between neighboring pixels, as described above.

In particular, leakage current may be reduced by electrically disconnecting the first functional layer FL1, the light emitting layers EL1, EL2, and the second functional layer FL2 between adjacent pixels through the first sub-layer SP1.

Additionally, since the second electrode E2 between adjacent pixels may be electrically connected through the second sub-layer SP2, a high-resolution display device may be stably provided.

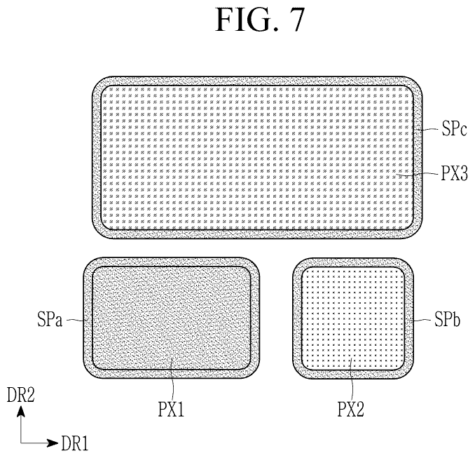

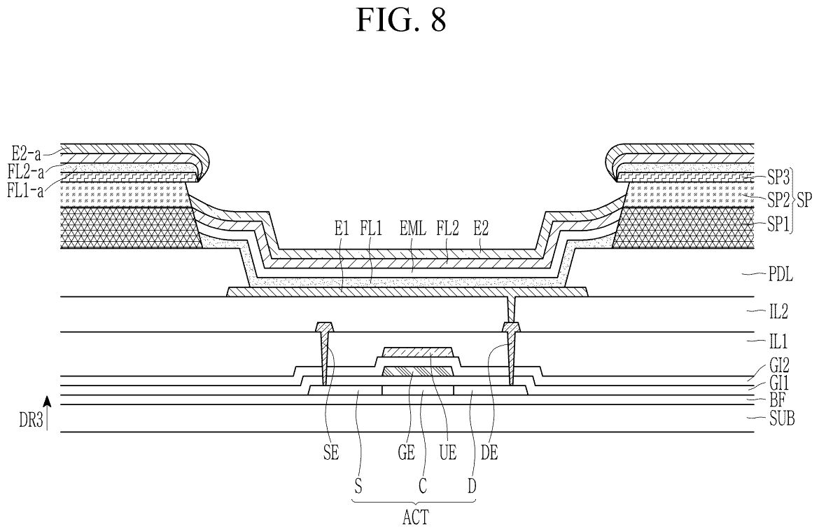

Hereinafter, another embodiment of FIG. 7 to FIG. 8 will be described.

FIG. 7 is a simplified plan view of multiple pixels according to an embodiment, and FIG. 8 is a simplified cross-sectional view of one pixel according to an embodiment.

Most descriptions of components that are the same as those described above may be omitted.

First, referring to FIG. 7, the separator SP according to an embodiment may be provided in a form surrounding each pixel PX1, PX2, and PX3.

The first separator SPa may independently surround the first pixel PX1.

The second separator SPb may independently surround the second pixel PX2.

The third separator SPc may independently surround the third pixel PX3.

Hereinafter, the stacked structure of the display device will be discussed with reference to FIG. 8.

A display device according to an embodiment may include a buffer layer BF, a semiconductor layer ACT, a first gate insulating layer GI1, a gate electrode GE, a second gate insulating layer GI2, an upper electrode UE, an interlayer insulating layer IL1, a source electrode SE and a drain electrode DE, a second insulating layer IL2, and a first electrode E1 arranged on a substrate SUB.

The first functional layer FL1, the emission layer EML, the second functional layer FL2, and the second electrode E2 may be sequentially located on the first electrode E1.

For detailed explanation, refer to the description of FIG. 2 above.

Meanwhile, the pixel defining layer PDL may be located on the first electrode E1.

The pixel defining layer PDL may have a pixel opening that overlaps the first electrode E1 and defines a light emitting area.

The pixel opening may have a planar shape substantially similar to that of the first electrode E1, and may have a diamond or octagonal shape similar to a diamond in a plan view, but is not limited thereto and may have any shape such as a square or polygon.

The separator SP may be located on the pixel defining layer PDL.

The separator SP may be formed to surround each pixel, as previously described in FIG. 7.

The separator SP may prevent lateral leakage current of the high-resolution structure by electrically disconnecting the functional layers FL1 and FL2, and the second electrode E2 between adjacent pixels.

The separator SP according to an embodiment may include the first sub-layer SP1, the second sub-layer SP2, and the third sub-layer SP3.

The first sub-layer SP1 may be located on the pixel defining layer PDL and may include an insulating material.

The first sub-layer SP1 may include any material for insulating the functional layers FL1 and FL2 between adjacent pixels—for example, an inorganic insulating material including silicon nitride, silicon oxide, or silicon oxynitride, or an organic insulating material.

The second sub-layer SP2 may be located on the first sub-layer SP1.

An edge of the second sub-layer SP2 may overlap the first sub-layer SP1.

The cross-section of the second sub-layer SP2 may gradually become wider toward the first sub-layer SP1.

The cross-section of the first sub-layer SP1 may also have a shape that gradually becomes wider toward the pixel defining layer PDL.

The second sub-layer SP2 may include a metal material.

For example, the second sub-layer SP2 may include at least one of Mo, W, Ti, Al, and TiN.

The second sub-layer SP2 may electrically connect the second electrode E2 that is separated by the separator SP between adjacent pixels.

According to an embodiment, the ends of the first functional layer FL1, the light emitting layer EL1, and the second functional layer FL2 may contact the side surface of the first sub-layer SP1 surrounding one pixel.

The first functional layer FL1, the light emitting layer EL1, and second functional layer FL2 located in a pixel by the first sublayer SP1 containing insulating material may prevent current leakage between adjacent pixels by being separated from the first functional layer FL1, the light emitting layer, and second functional layer FL2 located in adjacent other pixels.

An end of the second electrode E2 may contact the side surface of the second sub-layer SP2.

The second electrode E2 located within a pixel may have a disconnected shape in an area overlapping the separator SP.

However, the second electrode SP, which is disconnected with the separator SP in between, may be electrically connected by contacting the second sub-layer SP2.

The third sub-layer SP3 may be located on the second sub-layer SP2.

A width of the third sub-layer SP3 may be greater than a width of the second sub-layer SP2.

According to the manufacturing process sequence, the first functional layer FL1, the light emitting layer EL1, the second functional layer FL2, and the second electrode E2 formed by full-surface deposition after the third sub-layer SP3 may be formed after the third sub-layer SP3, and it may be electrically disconnected by an undercut formed by the third sub-layer SP3 and the second sub-layer SP2.

At least a part of the first functional layer FL1-a, at least a part of the second functional layer FL2-a, and at least a part of the second electrode E2-a formed by entire layering may be located on the third sub-layer SP3.

Although not shown in this specification, at least a part of the light emitting layer EL1 may be located between a part of the first functional layer FL1-a and a part of the second functional layer FL2-a.

The third sub-layer SP3 may include a metal material, and for example, may include a different metal material from the second sub-layer SP2.

The thickness of the third sub-layer SP3 may be less than the thickness of the first sub-layer SP1.

The thickness of the third sub-layer SP3 may be less than or equal to the thickness of the second sub-layer SP2.

For example, the first sub-layer SP1 may include silicon nitride with a thickness of about 3000 angstroms, the second sub-layer SP2 may include molybdenum with a thickness of about 2000 angstroms, and the third sub-layer SP3 may include titanium with a thickness of about 1000 angstroms.

For example, the first sublayer SP1 may contain silicon dioxide with a thickness of about 4000 angstroms, the second sublayer SP2 may contain molybdenum with a thickness of about 1000 angstroms, and the third sublayer SP3 may contain titanium with a thickness of about 1000 angstroms.

The separator SP according to an embodiment may reduce leakage current by electrically disconnecting the first functional layer FL1, the light emitting layer EL1, and the second functional layer FL2 between adjacent pixels through the first sub-layer SP1.

The second electrode E2 between adjacent pixels may be electrically connected through the second sub-layer SP2.

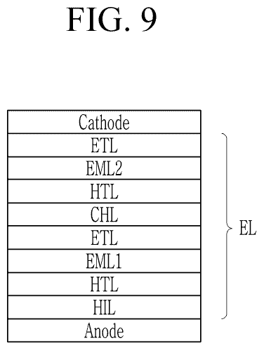

Hereinafter, a detailed stacked structure of a light emitting element according to an embodiment will be described with reference to FIG. 9.

FIG. 9 shows a stacked structure of a light emitting element according to an embodiment.

In FIG. 9, the stacked structure of the intermediate layer EL located between the anode and the cathode is shown in detail.

In FIG. 9, the light emitting element according to an embodiment may include multiple light emitting layers (EML1 and EML2), and hereinafter, this is also referred to as a tandem structure.

In the embodiment of FIG. 9, a total of two light emitting layers EML1 and EML2 may be included between the anode and the cathode.

Above and below the light emitting layer EML1, the hole injection layer HIL, the hole transport layer HTL, the electron transport layer ETL, and the connection layer CHL may be included.

Depending on the embodiment, an electron injection layer may also be included.

Specifically, in the embodiment of FIG. 9, the hole injection layer HIL and the hole transport layer HTL may be sequentially located on the anode, and the first color light emitting layer EML1 may be located on the anode.

The electron transport layer ETL, the connection layer CHL, and the hole transport layer HTL may be located sequentially on the first color emitting layer EML1, and the second color emitting layer EML2 may be located on top of the first color emitting layer EML1.

The electron transport layer ETL may be located on the second color emitting layer EML2, and the cathode may be located on it.

Here, the connection layer CHL may be located between the electron transport layer ETL and the hole transport layer HTL, and may serve to lower the Fermi barrier between the two layers.

The connection layer CHL may also be called a charge generation layer.

Depending on the embodiment, the light emitting element may include at least two light emitting layers, and although this specification describes an embodiment including two light emitting layers, the light emitting element is not limited thereto and may include three light emitting layers, four light emitting layers, etc.

A light emitting element according to an embodiment may have a tandem structure as shown in FIG. 9.

Parts from the hole injection layer HIL located on the first electrode E1 to the electron transport layer ETL located at the bottom of the second electrode E2, may be in contact with the first sub-layer SP1, and the second electrode E2 may be in contact with the second sub-layer SP2.

For this contact, the thickness of the first sub-layer SP1 and the second sub-layer SP2 may be adjusted. For example, the second sub-layer SP2 may have a minimum thickness for contacting the second electrode E2.

For example, the first sub-layer SP1 may include silicon nitride with a thickness of about 5000 angstroms, the second sub-layer SP2 may include molybdenum with a thickness of about 2000 angstroms, and the third sub-layer SP3 may include titanium with a thickness of about 1000 angstroms.

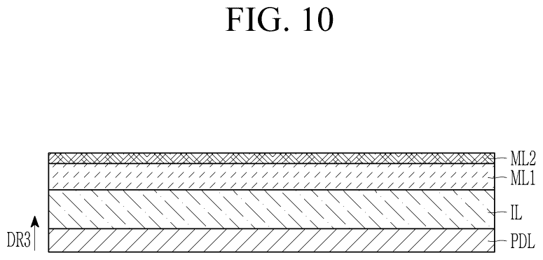

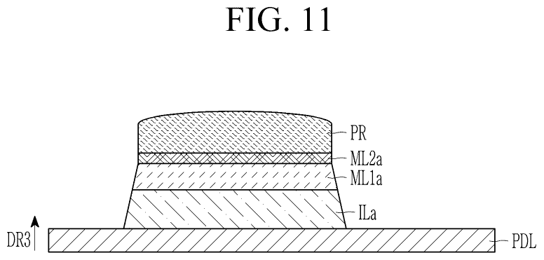

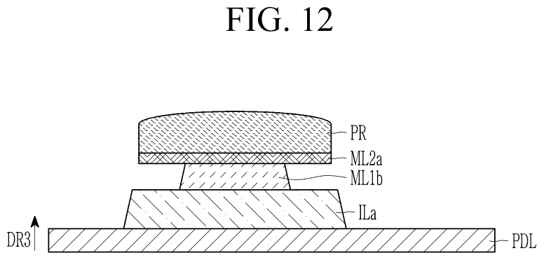

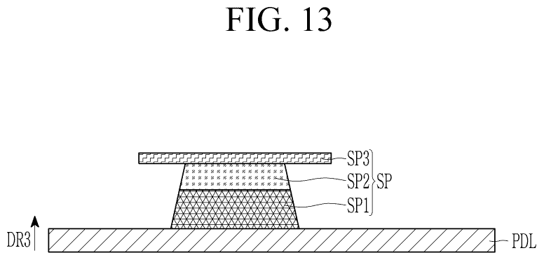

Hereinafter, a method of manufacturing a display device according to an embodiment will be described with reference to FIG. 10 to FIG. 13.

FIG. 10, FIG. 11, FIG. 12, and FIG. 13 schematically illustrate a method of manufacturing a display device according to an embodiment.

In particular, FIG. 10 to FIG. 13 illustrate a method of manufacturing a separator according to an embodiment.

First, referring to FIG. 10, according to a method of manufacturing a display device according to an embodiment, an insulating layer IL, a first metal layer ML1, and a second metal layer ML2 may be formed on the pixel defining layer PDL.

The insulating layer IL may include an inorganic insulating material including, e.g., silicon nitride, silicon oxide, or silicon nitride, or an organic insulating material.

Each of the first metal layer ML1 and the second metal layer ML2 may independently include, e.g., at least one of Mo, W, Ti, Al, and TiN.

The thickness of the insulating layer IL may be greater than the thickness of the first metal layer ML1 and the second metal layer ML2.

Of the sum of the thicknesses of the insulating layer IL and the first metal layer ML1, the thickness of the insulating layer IL may be more than one-half of the thickness, and the thickness of the first metal layer ML1 may be less than one-half of the thickness.

For example, the insulating layer IL may include silicon nitride with a thickness of about 3000 angstroms, the first metal layer ML1 may include molybdenum with a thickness of about 2000 angstroms, and the second metal layer ML2 may include titanium with a thickness of about 1000 angstroms.

As another example, the insulating layer IL may include silicon oxide with a thickness of about 4000 angstroms, the first metal layer ML1 may include molybdenum with a thickness of about 1000 angstroms, and the second metal layer ML2 may include titanium with a thickness of about 1000 angstroms.

Next, after forming the photosensitive pattern PR on the second metal layer ML2, the second metal layer ML2, the first metal layer ML1, and the insulating layer IL may be etched using the photosensitive pattern PR as a mask.

The second metal layer ML2a, the first metal layer ML1a, and the insulating layer ILa may be formed in an etched form as shown in FIG. 11.

Then, the first metal layer ML1b may be further etched using a wet etching process or a dry etching process, and an undercut may be formed as shown in FIG. 12.

The insulating layer ILa may be further etched using the following chemical dry etching process to form a separator including the first sub-layer SP1, the second sub-layer SP2, and the third sub-layer SP3 as shown in FIG. 13.

The separator SP formed according to the above-described manufacturing method may include a first sub-layer SP1 including an insulating material that electrically disconnects a first functional layer FL1, a light emitting layer EL1, EL2, and a second functional layer FL2, and the leakage current may be reduced.

Additionally, the second electrode E2 between adjacent pixels may be electrically connected through the second sub-layer SP2 containing a metal material.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a transistor located on a substrate;
a first electrode electrically connected to the transistor;
a first functional layer located on the first electrode;
a light emitting layer located on the first functional layer;
a second functional layer located on the light emitting layer;
a second electrode located on the second functional layer;
a pixel defining layer located on the first electrode; and
a separator located on the pixel defining layer, wherein
the separator comprises:
a first sub-layer comprising an insulating material; and
a second sub-layer located on the first sub-layer and including a metal material, and
an end of the second electrode contacts a side surface of the second sub-layer.

2. The display device of claim 1, wherein
the separator further includes a third sub-layer located on the second sub-layer, and
a width of the third sub-layer is greater than a width of the second sub-layer.

3. The display device of claim 2, wherein the third sub-layer has a metal material.

4. The display device of claim 1, wherein
the first sub-layer has a first thickness,
the second sub-layer has a second thickness, and
the first thickness is greater than the second thickness.

5. The display device of claim 4, wherein
the first thickness is greater than one-half of a sum of the first thickness and the second thickness, and
the second thickness is less than one-half of a sum of the first thickness and the second thickness.

6. The display device of claim 4, wherein an end of the first functional layer contacts a side of the first sub-layer.

7. The display device of claim 6, wherein the first functional layer includes a conductive hole injection layer.

8. The display device of claim 1, wherein the first sub-layer includes silicon nitride, silicon oxide, silicon nitrate, or an organic insulating material.

9. The display device of claim 2, wherein the second sub-layer and the third sub-layer include at least one of Mo, W, Ti, Al, and TiN.

10. The display device of claim 1, wherein an end of the light emitting layer and an end of the second functional layer contact a side surface of the first sub-layer.

11. The display device of claim 1, wherein the first functional layer, the second functional layer, and the second electrode are electrically disconnected between adjacent light emitting areas.

12. A display device comprising:
a transistor located on a substrate;
a first electrode electrically connected to the transistor;
a first functional layer located on the first electrode;
a light emitting layer located on the first functional layer;
a second functional layer located on the light emitting layer;
a second electrode located on the second functional layer;
a pixel defining layer located on the first electrode; and
a separator located on the pixel defining layer, wherein
the separator comprises
a first sub-layer comprising an insulating material;
a second sub-layer located on the first sub-layer and including a metal material; and
a third sub-layer located on the second sub-layer,
the first sub-layer has a first thickness,
the second sub-layer has a second thickness, and
the first thickness is greater than the second thickness.

13. The display device of claim 12, wherein a width of the third sub-layer is greater than a width of the second sub-layer.

14. The display device of claim 12, wherein
an end of the second electrode contacts a side surface of the second sub-layer, and
an end of the first functional layer contacts a side surface of the first sub-layer.

15. The display device of claim 12, wherein
the first thickness is greater than one-half of a sum of the first thickness and the second thickness, and
the second thickness is less than one-half of a sum of the first thickness and the second thickness.

16. The display device of claim 12, wherein the first functional layer includes a hole injection layer having conductivity.

17. The display device of claim 12, wherein ends of the light emitting layer and the second functional layer contact a side surface of the first sub-layer.

18. The display device of claim 12, wherein the first functional layer, the second functional layer, and the second electrode are electrically disconnected between adjacent light emitting areas.

19. The display device of claim 12, further comprising:
at least two light emitting layers that overlap in a direction perpendicular to the substrate.

20. The display device of claim 19, wherein
the at least two light emitting layers contact a side surface of the first sub-layer.
